(19) United States
(12) Patent Application Publication
(10) Pub. No.: US 2009/0008731 A1
(43) Pub. Date: Jan. 8, 2009

(54) Image Sensor and Method for Manufacturing the Same

(76) Inventor: Hong Lae Kim, Icheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/166,416

(22) Filed: Jul. 2, 2008

(30) Foreign Application Priority Data
Jul. 5, 2007 (KR) 10-2007-0067387

(51) Int. Cl. H01L 31/0232; H01L 31/18

(52) U.S. Cl. 257/432; 438/70; 257/E31.127

(57) ABSTRACT

An image sensor and method of manufacturing the same are provided. The image sensor can include a photodiode on a substrate, an interlayer insulation layer on the photodiode, and a color filter layer on the interlayer insulation layer. The color filter layer can include a nonsensitive color resin.

### CROSS REFERENCE TO RELATED APPLICATION

The present application claims the benefit under 35 U.S.C. §119 of Korean Patent Application No. 10-2007-0067387, filed Jul. 5, 2007, which is hereby incorporated by reference in its entirety.

### BACKGROUND

A CMOS image sensor (CIS) is an image sensor that sequentially detects electrical signals of respective unit-pixels to obtain an image in a switching scheme. Each unit pixel of the CIS typically includes a photodiode and at least one MOS transistor.

In a related art method of manufacturing an image sensor, a color filter is formed by coating the substrate with a negative photoresist and then performing a patterning of color process using a stepper. The color filter often is formed as an R-G-B color filter (red-green-blue color filter).

However, in the related art, the patterning resolution has a limit when patterning the negative photoresist such that a pixel size becomes large. Accordingly, there is a difficulty in producing CIS products of a high resolution.

Furthermore, the chip size used to produce conventional CIS products is large, resulting in a low yield.

### BRIEF SUMMARY

Certain embodiments of the present invention provide an image sensor and a method of manufacturing the same, capable of substantially reducing a pixel size of image sensor products and thus increasing a resolution.

In addition, embodiments of the present invention can provide an image sensor and a method of manufacturing the same using nonsensitive color resin, not a photoresponsive photoresist for forming a color filter.

According to an embodiment of the present invention, an image sensor can comprise a photodiode on a substrate, an interlayer insulation layer on the photodiode, and a color filter layer on the interlayer insulation layer. The color filter layer can comprise a nonsensitive color resin.

According to another embodiment of the present invention, a method of manufacturing an image sensor can comprise: forming a first layer on a substrate; forming a first trench on the first layer; forming a first color filter in the first trench; forming a second trench on the first layer at a side of the first color filter; forming a second color filter in the second trench; forming a third trench at a side of the second color filter; and forming a third color filter in the third trench. The first color filter can comprise a first nonsensitive color resin, the second color filter can comprise a second nonsensitive color resin, and the third color filter can comprise a third nonsensitive color resin. In a further embodiment, the first nonsensitive color resin, the second nonsensitive color resin, and the third nonsensitive color resin can each comprise the same resin material.

### BRIEF DESCRIPTION OF THE DRAWINGS

FIG. 1A is a plan view of an image sensor according to an embodiment of the present invention.

FIG. 1B is a cross-sectional view of an image sensor, taken along line I-I′ of FIG. 1A, according to an embodiment of the present invention.

FIG. 2 is a plan view of a green color filter of an image sensor according to an embodiment of the present invention.

FIGS. 3A and 3B are cross-sectional views illustrating a manufacturing process for a green color filter of an image sensor, taken along line II-II′ of FIG. 2, according to an embodiment of the present invention.

FIG. 4 is a plan view for illustrating a blue color filter of an image sensor according to an embodiment of the present invention.

FIGS. 5A and 5B are cross-sectional views taken along line III-III′ of FIG. 4 illustrating a manufacturing process for a blue color filter of an image sensor according to an embodiment of the present invention.

FIG. 6 is a plan view of a red color filter of an image sensor according to an embodiment of the present invention.

FIG. 7 is a cross-sectional view, taken along line IV-IV′ of FIG. 6, of a red color filter of an image sensor according to an embodiment of the present invention.

### DETAILED DESCRIPTION

Hereinafter, an image sensor and a method of manufacturing the same are described according to embodiments of the present invention with reference to the accompanying drawings.

When the terms “on” or “over” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

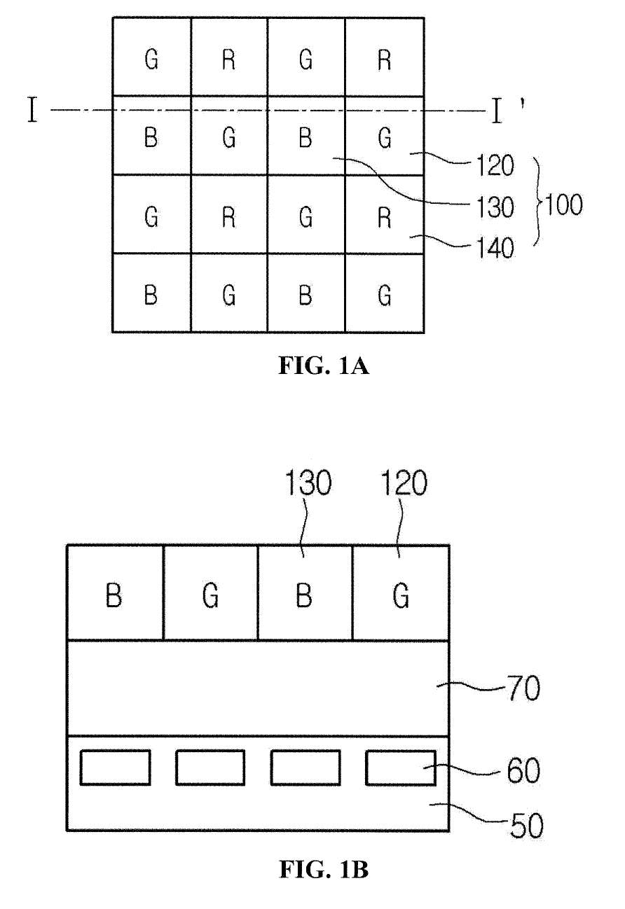

FIG. 1A is a plan view of an image sensor according to an embodiment of the present invention, and FIG. 1B is a cross-sectional view taken along line I-I′ of FIG. 1A according to an embodiment of the present invention.

According to an embodiment, an image sensor can include: a photodiode 60 formed on a substrate 50; an interlayer insulation layer 70 formed on the photodiode 60; and a color filter layer 100 on the interlayer insulation layer 70. In certain embodiments, the color filter layer 100 can be formed of nonsensitive color resin.

The color filter layer 100 can comprise, for example, a green color filter 120, a blue color filter 130, and a red color filter 140.

In an image sensor according to an embodiment of the present invention, a color filter layer can be formed of nonsensitive color resin, instead of photoresponsive color resin. Also, the nonsensitive color resin can be, for example, high-performance color resin.

In addition, according to an embodiment of the present invention, forming a color filter layer of nonsensitive color resin, instead of photoresponsive color resin, can help the image sensor attain a pixel size capable of getting a level of resolution corresponding to a photo apparatus, such as KrF/ArF source photo apparatus. Embodiments can be used for high-resolution image sensors.

A method of manufacturing an image sensor according to embodiments will now be described.

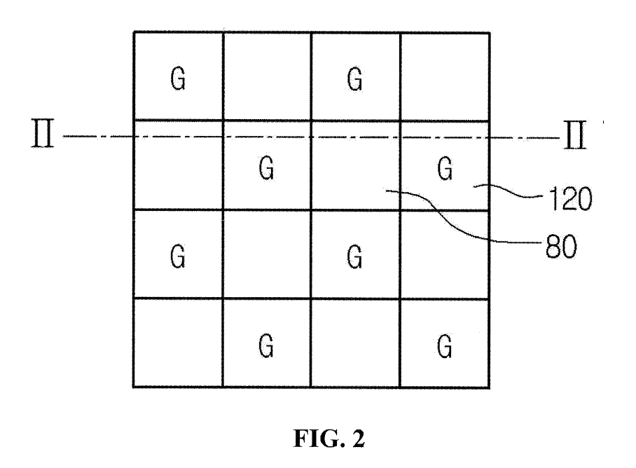

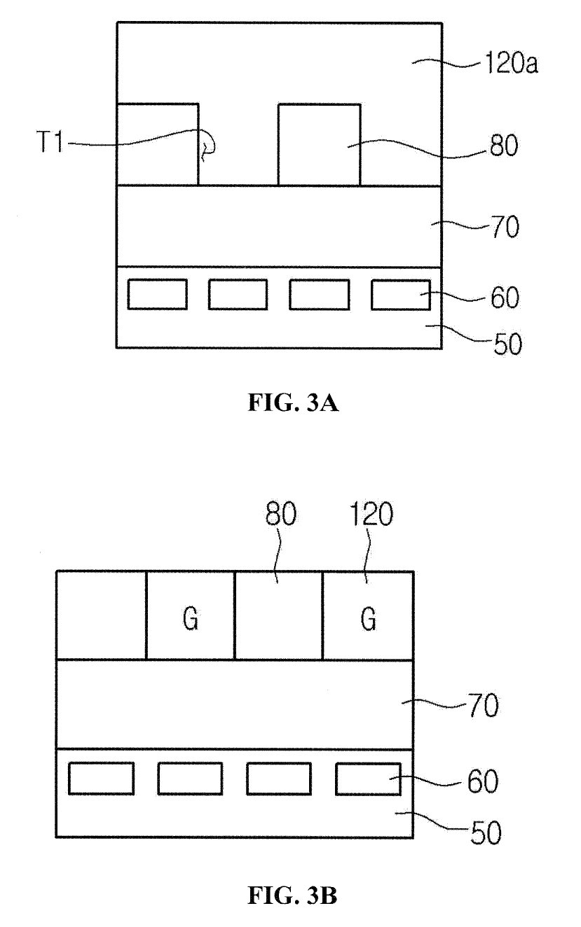

FIGS. 3A and 3B are cross-sectional views taken along line II-II′ of FIG. 2 for illustrating a manufacturing process of a green color filter of an image sensor according to an embodiment of the present invention.

Referring to FIG. 3A, a photodiode 60 can be formed on a substrate 50. In an embodiment, the photodiode 60 can be formed horizontally with a transistor (not shown). In an alternative embodiment, the invention is applicable to an above-IC type image sensor for which a photodiode can be formed vertically to a transistor region.

Then, an interlayer insulation layer 70 can be formed on the substrate 50 including the photodiode 60. In certain embodiments, the interlayer insulation layer 70 can be formed of multilayers. For example, the interlayer insulation layer 70 can be formed by forming a first interlayer insulation layer (not shown), then forming a shield layer (not shown) to inhibit light from being incident on a portion of the substrate 50 that is not a region of the photodiode 60, and then forming a second interlayer insulation layer (not shown).

In a further embodiment, a passivation layer (not shown) can be formed on the interlayer insulation layer 70 to help protect the device from moisture and scratches.

Then, a first layer 80 can be formed on the interlayer insulation layer 70.

The first layer 80 can be an insulation layer or a metal layer. For example, the first layer 80 can be an oxide layer, a nitride layer, an aluminum layer, or any other suitable layer known in the art.

Then, a first trench T1 can be formed on the first layer 80. The first trench T1 can be formed, for example, using an etching process.

A first color resin 120a can be formed in the first trench T1. The first color resin 120a can be a green color resin, but embodiments of the present invention are not limited thereto.

The first color resin 120a can be a nonsensitive color resin, instead of a photoresponsive color resin.

In one embodiment, the first color resin 120a can be a nonsensitive polyimide resin.

In another embodiment, the first color resin 120a can be a nonsensitive transparent resin. According to embodiments, the nonsensitive transparent resin may not have an ethylene unsaturated double bond. In certain embodiments, the nonsensitive transparent resin can be a thermoplastic resin, for example, butyral resin, styrene-maleic-acid copolymers, chlorinated polyethylene, chlorinated polypropylene, polyvinyl chloride, chloridevinyl-acetate acid vinyl copolymers, poly acetate acid vinyl, polyurethane resin, polyester resin, acrylic-group resin, alkyd resin, styrene resin, polyamide resin, rubber-group resin, cyclized rubber-group resin, cellulose-group, polybutadiene, polyimide resin, etc.

In an embodiment, the first color resin 120a can be a thermosetting resin for example, epoxy resin, benzoguanamine resin, maleic-acid resin modified with rosin, fumaric acid resin modified with rosin, phenolic resin, melamine resin, urea-formaldehyde resin, etc.

In a further embodiment, the first color resin 120a can be an alkali-type nonsensitive transparent resin. The alkali-type nonsensitive transparent resin can help form a filter segment through an alkali effect using a coloring composition.

In one embodiment, the first color resin 120a can be a nonsensitive transparent resin of the alkali-type and can have properties of being dissolved in alkali water solution, and can be transparent resin not having an ethylene-unsaturated double bond. Additionally, the first color resin 120a can be a nonsensitive transparent resin with a weight-mean molecular weight of from about 1,000 to about 500,000 g/mol and can have an acid functionality, for example, carboxyl, sulfonic, etc. The acid functionality can be carboxyle, and an acid value of the nonsensitive transparent resin can be higher than an acid value of photosensitive transparent resin, in order to obtain a stabilized distribution of coloring composition for a color filter and to get an increase in developing performance. In an embodiment, a patterning characteristic of film can be satisfied in the coloring formed of the color-filter coloring composition, and a filter segment of stabilized shape can be achieved.

In an embodiment, the first color resin 120a can be a nonsensitive transparent resin of an alkali, for example, an acrylic resin having an acid functionality, such as a-olefin/maleic-acid anhydride copolymers, styrene/maleic-acid anhydride copolymers, styrene/styrene sulfonic acid copolymers, ethylene/(meta) acrylic acid copolymers, isobutylene/maleic-acid anhydride copolymers, etc.

Referring to FIG. 3B, the first color resin 120a can be planarized to expose the first layer 80 to form a first color filter 120. The first color resin 120a can be planarized using any suitable process known in the art. For example, the first color resin 120a can be planarized through a chemical mechanical polishing (CMP) process or an etch-back process.

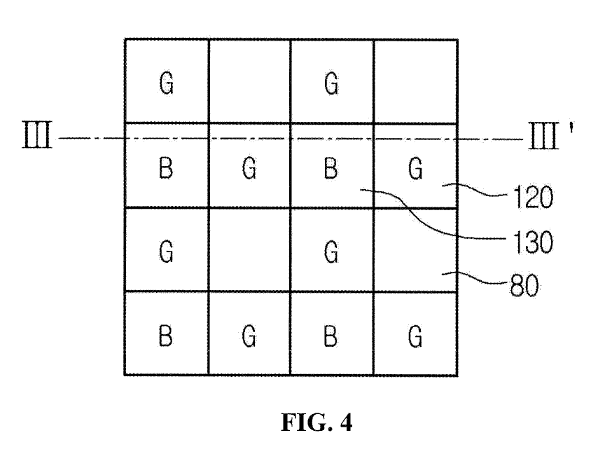

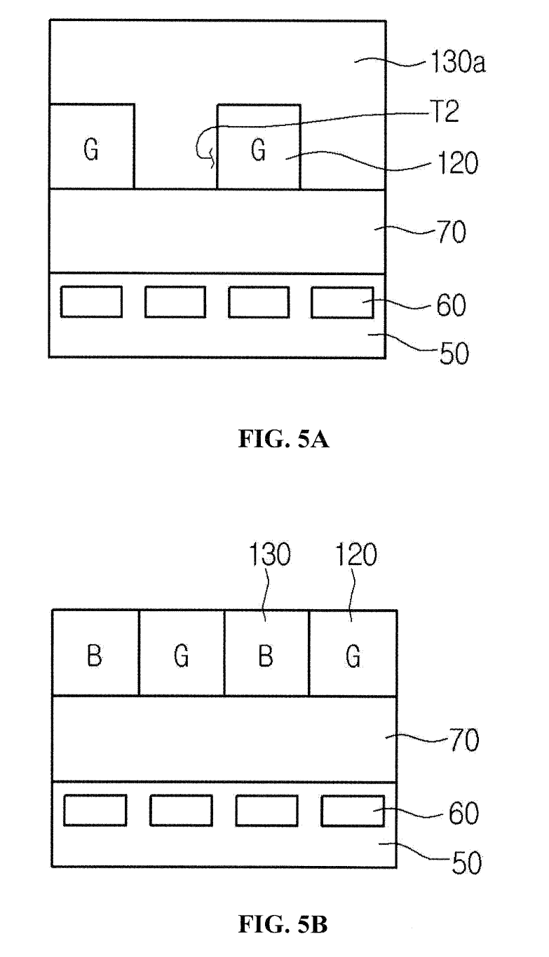

FIGS. 5A and 5B are cross-sectional views for illustrating a manufacturing process of a blue color filter of an image sensor, taken along line III-III′ of FIG. 4, according to an embodiment of the present invention.

Referring to FIG. 5A, a second trench T2 can be formed on the first layer 80 at a side of the first color filter 120.

Then, a second color resin 130a can be formed in the second trench T2. The second color resin 130a can be, for example, blue color resin, but embodiments of the present invention are not limited thereto.

The second color resin 130a can be a nonsensitive color resin, instead of a photoresponsive color resin.

In one embodiment, the second color resin 130a can be a nonsensitive polyimide resin.

In another embodiment, the second color resin 130a can be a nonsensitive transparent resin. According to embodiments, the nonsensitive transparent resin may not have an ethylene unsaturated double bond. In certain embodiments, the nonsensitive transparent resin can be a thermoplastic resin, for example, butyral resin, styrene-maleic-acid copolymers, chlorinated polyethylene, chlorinated polypropylene, polyvinyl chloride, chloridevinyl-acetate acid vinyl copolymers, poly acetate acid vinyl, polyurethane resin, polyester resin, acrylic-group resin, alkyd resin, styrene resin, polyamide resin, rubber-group resin, cyclized rubber-group resin, cellulose-group, polybutadiene, polyimide resin, etc.

In an embodiment, the second color resin 130a can be a thermosetting resin for example, epoxy resin, benzoguanamine resin, maleic-acid resin modified with rosin, fumaric acid resin modified with rosin, phenolic resin, melamine resin, urea-formaldehyde resin, etc.

In a further embodiment, the second color resin 130a can be an alkali-type nonsensitive transparent resin. The alkali-type nonsensitive transparent resin can help form a filter segment through an alkali effect using a coloring composition.

In one embodiment, the second color resin 130a can be a nonsensitive transparent resin of the alkali-type and can have properties of being dissolved in alkali water solution, and can be transparent resin not having an ethylene-unsaturated double bond. Additionally, the second color resin 130a can be a nonsensitive transparent resin with a weight-mean molecular weight of from about 1,000 to about 500,000 g/mol and can have an acid functionality, for example, carboxyl, sulfonic, etc. The acid functionality can be carboxyl, and an acid value of the nonsensitive transparent resin can be higher than an acid value of photosensitive transparent resin, in order to obtain a stabilized distribution of coloring composition for a color filter and to get an increase in developing performance. In an embodiment, a patterning characteristic of film can be satisfied in the coloring formed of the color-filter coloring composition, and a filter segment of stabilized shape can be achieved.

In an embodiment, the second color resin 130a can be a nonsensitive transparent resin of an alkali, for example, an acrylic resin having an acid functionality, such as α-olefin/maleic-acid anhydride copolymers, styrene/maleic-acid anhydride copolymers, styrene/styrene sulfonic acid copolymers, ethylene/(meta) acrylic acid copolymers, isobutylene/maleic-acid anhydride copolymers, etc.

Referring to FIG. 4B, the second color resin 130a can be planarized to expose the first layer 80, to form a second color filter 130. The second color resin 130a can be planarized using any suitable process known in the art. For example, the second color resin 130a can be planarized through a CMP process or an etch-back process.

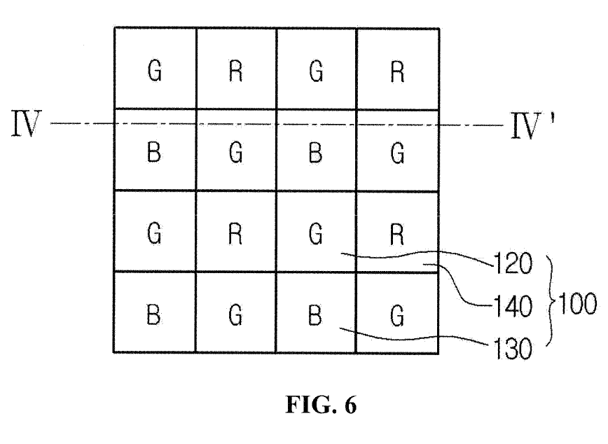

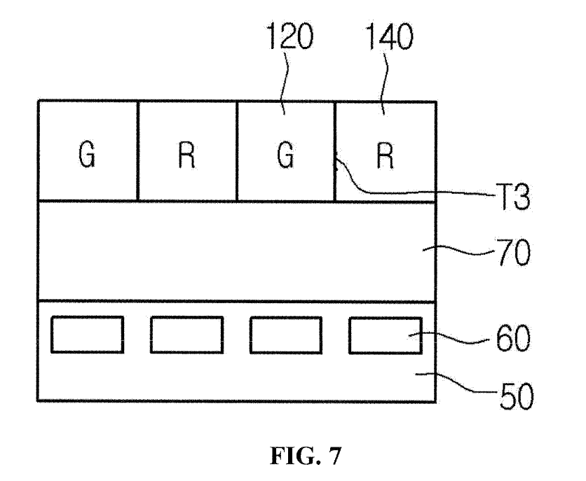

FIG. 7 is a cross-sectional view of a red color filter of an image sensor, taken along line IV-IV′ of FIG. 6, according to an embodiment of the present invention.

Referring to FIG. 7, a third trench T3 can be formed on the first layer 80 at a side of the second color filter 130.

Then, a third color resin (not shown) can be formed in the third trench T3. The third color resin (not shown) can be, for example, red color resin, but embodiments of the present invention are not limited thereto.

The third color resin can be a nonsensitive color resin, instead of photoresponsive color resin.

In one embodiment, the third color resin can be a nonsensitive polyimide resin.

In another embodiment, the third color resin can be a nonsensitive transparent resin. According to embodiments, the nonsensitive transparent resin may not have an ethylene unsaturated double bond. In certain embodiments, the nonsensitive transparent resin can be a thermoplastic resin, for example, butyral resin, styrene-maleic-acid copolymers, chlorinated polyethylene, chlorinated polypropylene, polyvinyl chloride, chloridevinyl-acetate acid vinyl copolymers, poly acetate acid vinyl, polyurethane resin, polyester resin, acrylic-group resin, alkyd resin, styrene resin, polyamide resin, rubber-group resin, cyclized rubber-group resin, cellulose-group, polybutadiene, polyimide resin, etc.

In an embodiment, the third color resin can be a thermosetting resin for example, epoxy resin, benzoguanamine resin, maleic-acid resin modified with rosin, fumaric acid resin modified with rosin, phenolic resin, melamine resin, urea-formaldehyde resin, etc.

In a further embodiment, the third color resin can be an alkali-type nonsensitive transparent resin. The alkali-type nonsensitive transparent resin can help form a filter segment through an alkali effect using a coloring composition.

In one embodiment, the third color resin can be a nonsensitive transparent resin of the alkali-type and can have properties of being dissolved in alkali water solution, and can be transparent resin not having an ethylene-unsaturated double bond. Additionally, the third color resin can be a nonsensitive transparent resin with a weight-mean molecular weight of from about 1,000 to about 500,000 g/mol and can have an acid functionality, for example, carboxyl, sulfonic, etc. The acid functionality can be carboxyl, and an acid value of the nonsensitive transparent resin can be higher than an acid value of photosensitive transparent resin, in order to obtain a stabilized distribution of coloring composition for a color filter and to get an increase in developing performance. In an embodiment, a patterning characteristic of film can be satisfied in the coloring formed of the color-filter coloring composition, and a filter segment of stabilized shape can be achieved.

In an embodiment, the third color resin can be a nonsensitive transparent resin of an alkali, for example, an acrylic resin having an acid functionality, such as a-olefin/maleic-acid anhydride copolymers, styrene/maleic-acid anhydride copolymers, styrene/styrene sulfonic acid copolymers, ethylene/(meta) acrylic acid copolymers, isobutylene/maleic-acid anhydride copolymers, etc.

Then, the third color resin can be planarized to expose the first layer 80, to form a third color filter 140, thereby providing a color filter layer 100 of the image sensor according to embodiments of the present invention. The third color resin can be planarized using any suitable process known in the art. For example, the third color resin can be planarized through a CMP process or an etch-back process.

In an embodiment, a planarization layer (not shown) can be formed on the color filter layer 100, and a microlens (not shown) can be formed.

It is to be understood that, in various embodiments of the present invention, the first color resin, the second color resin, and the third color resin can all comprise the same resin material, or any two of the color resins can comprise the same resin material while the third comprises a different resin material, or all three color resins can each comprise different resin materials.

In an image sensor and a method of manufacturing the same according to embodiments of the present invention, a pixel size can be provided to attain a level of resolution corresponding to that of the photo apparatus being used, such as a KrF/ArF source photo apparatus. Accordingly, embodiments can be used for high-resolution image sensors.

In addition, according to certain embodiments of the present invention, a color filter can be formed without using photoresponsive color resin, instead employing a high-performance color resin.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor, comprising:
a photodiode on a substrate;
an interlayer insulation layer on the photodiode; and
a color filter layer on the interlayer insulation layer, wherein the color filter layer comprises a nonsensitive color resin.

2. The image sensor according to claim 1, wherein the nonsensitive color resin is a nonsensitive polyimide resin.

3. The image sensor according to claim 1, wherein the nonsensitive color resin is a nonsensitive transparent resin.

4. The image sensor according to claim 3, wherein the nonsensitive transparent resin does not have an ethylene unsaturated double bond.

5. The image sensor according to claim 3, wherein the nonsensitive transparent resin is a thermoplastic resin.

6. The image sensor according to claim 3, wherein the nonsensitive transparent resin is butyral resin, styrene-maleic-acid copolymers, chlorinated polyethylene, chlorinated polypropylene, polyvinyl chloride, chloridevinyl-acetate acid vinyl copolymers, poly acetate acid vinyl, polyurethane resin, polyester resin, acrylic-group resin, alkyd resin, styrene resin, polyamide resin, rubber-group resin, cyclized rubber-group resin, cellulose-group, polybutadiene, or polyimide resin.

7. The image sensor according to claim 3, wherein the nonsensitive transparent resin is an alkali-type resin.

8. The image sensor according to claim 7, wherein the alkali-type resin has a weight-mean molecular weight of from about 1,000 g/mol to about 500,000 g/mol and has an acid functionality.

9. The image sensor according to claim 1, wherein the nonsensitive color resin is a thermosetting resin.

10. The image sensor according to claim 9, wherein the thermosetting resin is epoxy resin, benzoguanamine resin, maleic-acid resin modified with rosin, fumaric acid resin modified with rosin, phenolic resin, melamine resin, or urea-formaldehyde resin.

11. A method of manufacturing an image sensor, comprising:
forming a first layer on a substrate;
forming a first trench in the first layer;
forming a first color filter in the first trench;
forming a second trench in the first layer at a side of the first color filter;
forming a second color filter in the second trench;
forming a third trench in the first layer at a side of the second color filter; and
forming a third color filter in the third trench;
wherein the first color filter comprises a first nonsensitive color resin, and wherein the second color filter comprises a second nonsensitive color resin, and wherein the third color filter comprises a third nonsensitive color resin.

12. The method according to claim 11, wherein the first layer is an insulation layer or a metal layer.

13. The method according to claim 11, wherein the first nonsensitive color resin, the second nonsensitive color resin and the third nonsensitive color resin each comprise the same resin material.

14. The method according to claim 11, wherein the first nonsensitive color resin is a nonsensitive polyimide resin, and wherein the second nonsensitive color resin is a nonsensitive polyimide resin, and wherein the third nonsensitive color resin is a nonsensitive polyimide resin.

15. The method according to claim 11, wherein the first nonsensitive color resin is a nonsensitive transparent resin, and wherein the second nonsensitive color resin is a nonsensitive transparent resin, and wherein the third nonsensitive color resin is a nonsensitive transparent resin.

16. The method according to claim 15, wherein the nonsensitive transparent resin does not have an ethylene unsaturated double bond.

17. The method according to claim 15, wherein the nonsensitive transparent resin is a thermoplastic resin.

18. The method according to claim 15, wherein the nonsensitive transparent resin is an alkali-type resin.

19. The method according to claim 18, wherein the alkali-type resin has a weight-mean molecular weight of from about 1,000 g/mol to about 500,000 g/mol and has an acid functionality.

20. The method according to claim 1, wherein the first nonsensitive color resin is a thermosetting resin, and wherein the second nonsensitive color resin is a thermosetting resin, and wherein the third nonsensitive color resin is a thermosetting resin.
